(19) United States
(12) Patent Application Publication
(10) Pub. No.: US 2024/0237260 A1
(43) Pub. Date: Jul. 11, 2024

(54) Buffer Structure for Immersed Server Slide Rail and Working Method

(71) Applicant: Asia Pacific CIS (Wuxi) Co. Ltd., Wuxi (CN)

(72) Inventor: Juanjuan Xie, Wuxi (CN)

(21) Appl. No.: 18/465,731

(22) Filed: Nov. 21, 2023

(30) Foreign Application Priority Data
Sep. 13, 2022 (CN) 202211111677.3

(51) Int. Cl. H05K 7/14; H05K 7/20

(52) U.S. Cl. CPC H05K 7/1489; H05K 7/20236; H05K 7/20772

(57) ABSTRACT

The present invention relates to a buffer structure for immersion server slide rail and a working method therefor, which belongs to the field of server slide rails. The buffer structure is composed of a buffer tank, buffer chambers, small holes, guide pins, elastic members and a buffering block. When the slide rail is open, due to the fact that the elastic members undergo a loss of compression, the guide pins and the buffering block are pushed to move outwards, the server's liquid coolant enters the buffer chambers through the small holes in the tail portion of the buffer tank and fills up the chambers, and the buffering block stops moving when abutting against the first position-limiting stopper; whereas when the slide rail is closed, the tail portion of the first moveable rail abuts against the buffering block to generate an inward thrust, pushing the buffering block and the guide pins to move inwards, and the guide pins press against the elastic members and the liquid coolant in the buffer chambers, thereby forming a buffer. In this way, the present invention is made to be structurally compact, rational, easy to operate, enabling automatic buffering, thereby preventing collision damage that may be caused by excessive impact during operation, reducing accidental damage that may be caused by undesirable operation, and prolonging the server's lifespan.

### TECHNICAL FIELD

The present invention relates to a buffer structure for immersion server slide rail and a working method therefor, which belongs to the field of server slide rails.

### BACKGROUND

Due to the increasing use of content streaming, cloud computing and industrial automation, the demand for data has never been greater, which means higher energy usage and efficient handling of heat-related problems. Immersion cooling solutions can easily accommodate the ever-increasing thermal loads of the latest processors while achieving ultra-low power consumption for energy savings and sustainability goals. It is estimated that the global data center liquid cooling market is expected to reach $6 billion by 2026. The high growth of the market is expected to be driven by the increasing demand for green and energy-efficient alternatives. Immersion servers help save valuable data center floor space and simplify deployment without sacrificing reliability, availability or serviceability. As an important accessory of immersion server, the demand for immersion server slide rails will increase. Compared with conventional air-cooled server slide rails, liquid-cooled servers can be installed vertically on the ground. In this scenario, after installation the server is prone to directly hitting the blocking point due to operational errors, causing internal and external damages to the server.

### SUMMARY OF THE INVENTION

Purpose of the invention: to provide a buffer structure for immersion server slide rail and a working method therefor to solve the abovementioned problems.

Technical solution: in a first aspect, a buffer structure for immersion server slide rail is provided, which is composed of a fixed rail and a moveable rail assembly and is immersed in a liquid coolant for server; the moveable rail assembly includes a first moveable rail and a second moveable rail.

In a further embodiment, the moveable rail assembly includes at least a first moveable rail and a second moveable rail, which can be increased or decreased depending on the requirements of the workplace.

In a further embodiment, an end of the fixed rail is provided with a buffer structure; the buffer structure includes: a buffer tank relatively fixedly mounted on the fixed rail, the head portion of the buffer tank is provided with buffer chambers, and the buffer chambers have a depth not greater than the length of the buffer tank, the tail portion of the buffer tank is provided with small holes, and the small holes communicate with the buffer chambers, respectively; guide pins and elastic members installed in the buffer chambers, and the elastic members are arranged between the bottoms of the guide pins and the bottoms of the buffer chambers, respectively; and a buffering block relatively fixed to the head portions of the guide pins.

In a further embodiment, the first moveable rail is located in the fixed rail, and the fixed rail and the first moveable rail are slidingly connected; the second moveable rail is located in the first moveable rail, and the second moveable rail and the first moveable rail are slidingly connected;

A sliding trestle is provided on an inner side of the fixed rail and an inner side of the first moveable rail, with the sliding trestle being provided with roller balls, the roller balls of the sliding trestle on the fixed rail have a simultaneous surface connection with the chute of the fixed rail and the chute of the first moveable rail, and the roller balls of the sliding trestle on the first moveable rail have a simultaneous surface connection with the chute of the first moveable rail and the chute of the second moveable rail;

The head portion of the fixed rail and the head portion of the first moveable rail are each provided with a stopper, which is in contact with the head portion of the sliding trestle.

In a further embodiment, two foolproof blocks are provided on the bottom surface of the buffer tank, two foolproof slots are opened on the fixed rail, and the foolproof blocks are located in the foolproof slots.

In a further embodiment, a raised first position-limiting stopper is provided on the fixed rail, and when the buffering block is stretched out, the first position-limiting stopper limits the maximum working distance of the buffering block;

The head portion of the first moveable rail and the head portion of the second moveable rail are each provided with a second position-limiting stopper that protrudes inwards, and when the slide rail is closed, the second position-limiting stoppers limit the maximum pushed-in distance of the first moveable rail and the second moveable rail.

In a further embodiment, an inner side of the tail portion of the first moveable rail and an inner side of the tail portion of the second moveable rail are each provided with an anti-detachment assembly;

The head portion of the fixed rail is provided with an inwardly protruding bump; the tail portion of the sliding trestle is provided with a boss;

The anti-detachment assembly includes: a paddle-like plate mounted on the first moveable rail by means of a rivet, with the boss located in a steer hole disposed at the tail portion of the paddle-like plate and the bump located in a position-limiting slot at the tail portion of the paddle-like plate; and an elastic pull rod connected between two pull-blocks on the paddle-like plate.

In a further embodiment, the small holes are connected externally to a liquid coolant.

In a further embodiment, the centers of the buffer chambers and the centers of the small holes are coaxial, respectively.

In a second aspect, a working method for immersion server slide rail is provided, which comprises slide rail opening buffering and slide rail closing buffering, specifically the steps of the working method are as follows:
Step 1: when opening the server slide rail, the first moveable rail is moved outwards on the fixed rail through the roller balls on the sliding trestle, the elastic members undergo a loss of pressure and push the guide pins and the buffering block to move outwards, and the liquid coolant of the server passes through the small holes in the tail portion of the buffer tank to enter the buffer chambers and fills up the chambers. When the buffering block abuts against the first position-limiting stopper, the second moveable rail is also moved outwards on the first moveable rail through the roller balls on the first moveable rail, thereby completing opening of the slide rail;
Step 2: when closing the server slide rail, the second moveable rail is moved inwards. The second moveable rail moves outwards on the first moveable rail through the roller balls on the sliding trestle. When the second moveable rail returns to its position, the first moveable rail moves inwards on the fixed rail through the roller balls on the sliding trestle. When the tail portion of the first moveable rail approaches the buffering block and comes in contact with the buffering block, it continues to move inwards and the inward thrust pushes the buffering block, the guide pins and the elastic members to undergo compression, and the guide pins push the server's liquid coolant in the buffer chambers to flow out of the small holes, thereby forming a buffer.

Beneficial effects: the present invention relates to a buffer structure for immersion server slide rail and a working method therefor, which belongs to the field of server slide rails. The buffer structure of the present invention is composed of a fixed rail, a first moveable rail and a second moveable rail; an end of the fixed rail is provided with a buffer structure, the buffer structure is composed of: a buffer tank, the head portion of the buffer tank being provided with buffer chambers, the tail portion of the buffer tank being provided with small holes, and the small holes communicating with the buffer chambers, respectively; guide pins and elastic members disposed in the buffer chambers, respectively; and a buffering block. When the slide rail is open, due to the fact that the elastic members undergo a loss of compression, the guide pins and the buffering block are pushed to move outwards, the server's liquid coolant enters the buffer chambers through the small holes in the tail portion of the buffer tank and fills up the chambers, and the buffering block stops moving when abutting against the first position-limiting stopper; whereas when the slide rail is closed, the tail portion of the first moveable rail abuts against the buffering block to generate an inward thrust, pushing the buffering block and the guide pins to move inwards, and the guide pins press against the elastic members and the liquid coolant in the buffer chambers, thereby forming a buffer. In this way, the present invention is made to be structurally compact, rational, easy to operate, enabling automatic buffering, thereby preventing collision damage that may be caused by excessive impact during operation, reducing accidental damage that may be caused by undesirable operation, and prolonging the server's lifespan.

### BRIEF DESCRIPTION OF THE DRAWINGS

FIG. 1 is an axonometric view of the present invention.

FIG. 2 is a front view of a buffer structure of the present invention.

FIG. 3 is a top view of the buffer structure of the present invention.

FIG. 4 is a top view of the buffer structure of the present invention.

FIG. 5 is a sectional view of the buffer structure of the present invention.

FIG. 6 is a front view of a first moveable rail of the present invention.

FIG. 7 is a schematic view of an anti-detachment assembly of the present invention.

FIG. 8 is a schematic view of an end portion of a fixed rail of the present invention.

FIG. 9 is a schematic view of a tail portion of the fixed rail and the first moveable rail of the present invention.

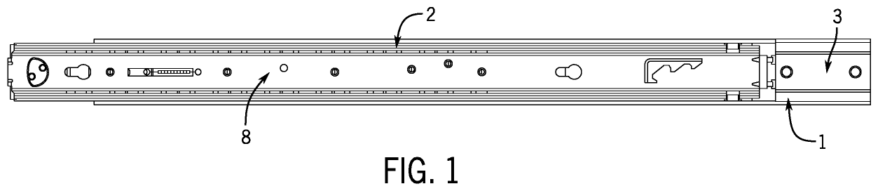

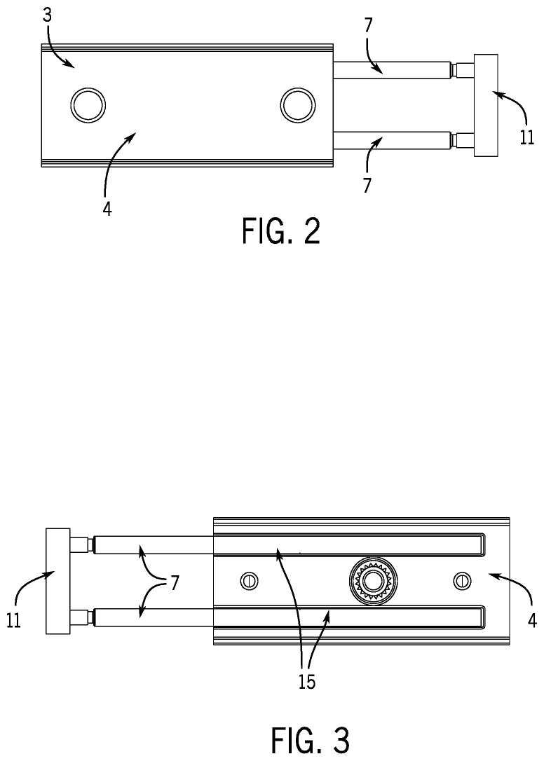

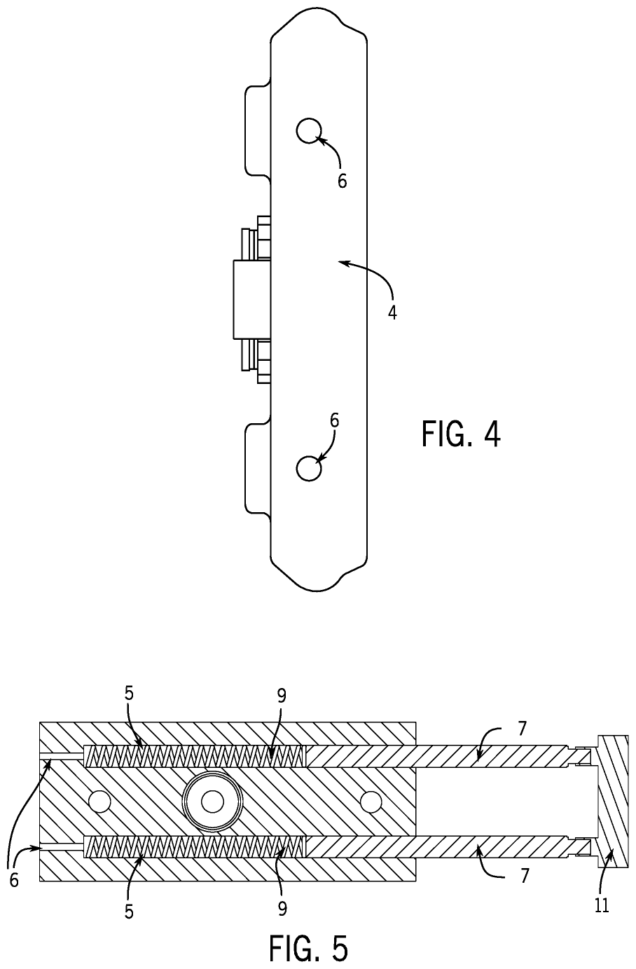

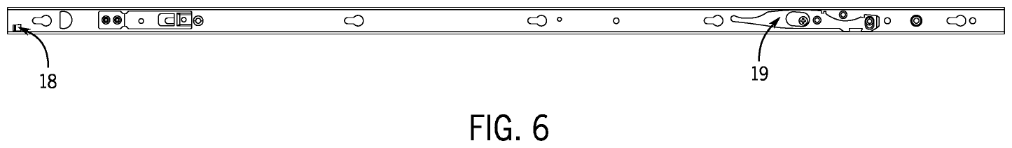

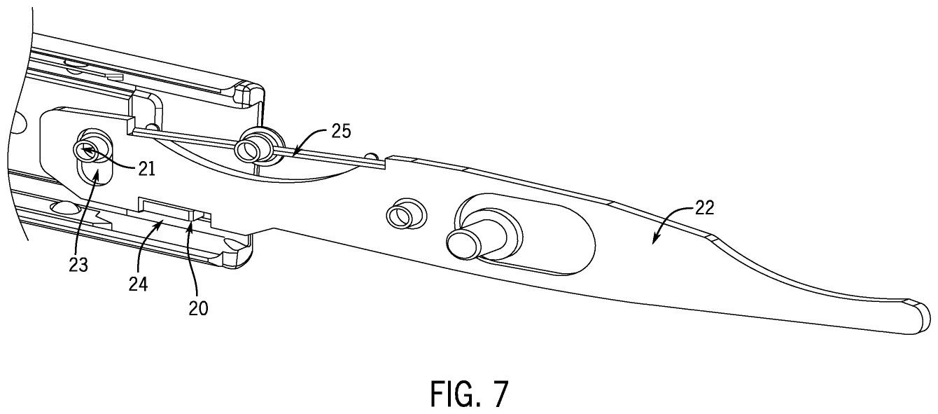

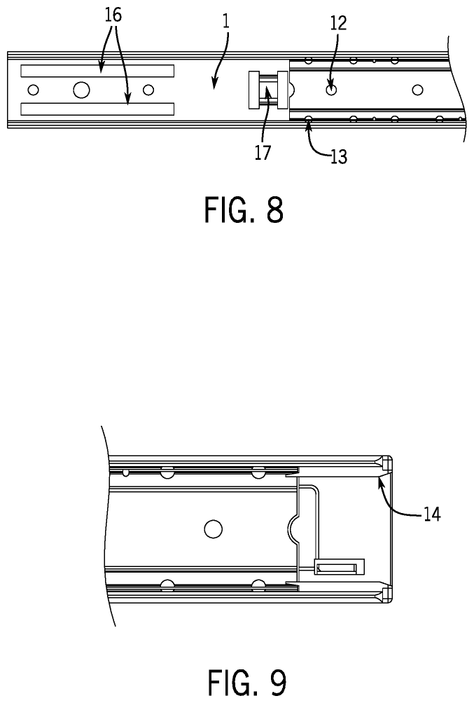

Reference numerals: 1 denotes fixed rail, 2 denotes first moveable rail, 3 denotes buffer structure, 4 denotes buffer tank, 5 denotes buffer chamber, 6 denotes small hole, 7 denotes guide pin, 8 denotes second moveable rail, 9 denotes elastic member, 11 denotes buffering block, 12 denotes sliding trestle, 13 denotes roller ball, 14 denotes stopper, 15 denotes foolproof block, 16 denotes foolproof slot, 17 denotes first position-limiting stopper, 18 denotes second position-limiting stopper, 19 denotes anti-detachment assembly, 20 denotes bump, 21 denotes boss, 22 denotes paddle-like plate, 23 denotes steer hole, 24 denotes position-limiting slot, and 25 denotes elastic pull rod.

### DETAILED DESCRIPTION

In the following description, numerous specific details are given in order to provide a more thorough understanding of the present invention. However, it will be apparent to those skilled in the art that the present invention may be practiced without one or more of these details; in other instances, certain technical features known in the art are omitted in order to avoid obscuring the present invention.

A buffer structure for immersion server slide rail is composed of a fixed rail and a moveable rail assembly, and is immersed in a liquid coolant for server; the moveable rail assembly includes a first moveable rail 2 and a second moveable rail 8.

In a further embodiment, the moveable rail assembly includes at least a first moveable rail 2 and a second moveable rail 8, which can be increased or decreased depending on the requirements of the workplace.

### Embodiment 1

An end of the fixed rail 1 is provided with a buffer structure 3; the buffer structure 3 includes: a buffer tank 4, buffer chambers 5, small holes 6, guide pins 7, elastic members 9, and a buffering block 11.

In one embodiment, the buffer tank 4 is relatively fixedly mounted on the fixed rail; the head portion of the buffer tank 4 is provided with buffer chambers 5; the buffer chambers 5 have a depth not greater than the length of the buffer tank 4; the tail portion of the buffer tank 4 is provided with small holes 6, and the small holes 6 communicate with the buffer chambers 5, respectively; the guide pins 7 and the elastic members 9 are installed in the buffer chambers 5, and the elastic members 9 are arranged between the bottoms of the guide pins 7 and the bottoms of the buffer chambers 5, respectively; the buffering block 11 is relatively fixed to the head portions of the guide pins 7.

In one embodiment, the centers of the buffer chambers 5 and the centers of the small holes 6 are coaxial, respectively.

In one embodiment, the small holes 6 are connected externally to a liquid coolant.

### Embodiment 2

The first moveable rail 2 is located in the fixed rail 1, and the fixed rail 1 and the first moveable rail 2 are slidingly connected; the second moveable rail 8 is located in the first moveable rail 2, and the second moveable rail 8 and the first moveable rail 2 are slidingly connected.

In one embodiment, a sliding trestle 12 is provided on an inner side of the fixed rail 1 and an inner side of the first moveable rail 2, with the sliding trestle 12 being provided with roller balls 13, the roller balls 13 of the sliding trestle 12 on the fixed rail 1 have a simultaneous surface connection with the chute of the fixed rail 1 and the chute of the first moveable rail 2, and the roller balls 13 of the sliding trestle 12 on the first moveable rail 2 have a simultaneous surface connection with the chute of the first moveable rail 2 and the chute of the second moveable rail 8.

In one embodiment, the head portion of the fixed rail 1 and the head portion of the first moveable rail 2 are each provided with a stopper 14, which is in contact with the head portion of the sliding trestle 12.

### Embodiment 3

Two foolproof blocks 15 are provided on the bottom surface of the buffer tank 4, two foolproof slots 16 are opened on the fixed rail 1, and the foolproof blocks 15 are located in the foolproof slots 16.

In one embodiment, a raised first position-limiting stopper 17 is provided on the fixed rail 1, and when the buffering block 11 is stretched out, the first position-limiting stopper 17 limits the maximum working distance of the buffering block 11; the head portion of the first moveable rail 2 and the head portion of the second moveable rail 8 are each provided with a second position-limiting stopper 18 that protrudes inwards, and when the slide rail is closed, the second position-limiting stoppers 18 limit the maximum pushed-in distance of the first moveable rail 2 and the second moveable rail 8.

### Embodiment 4

The first moveable rail 2 an inner side of the tail portion of the first moveable rail 2 and an inner side of the tail portion of the second moveable rail 8 are each provided with an anti-detachment assembly 19; the head portion of the fixed rail 1 is provided with an inwardly protruding bump 20; the tail portion of the sliding trestle 12 is provided with a boss 21.

In one embodiment, the anti-detachment assembly 19 includes: a paddle-like plate 22 mounted on the first moveable rail 2 by means of a rivet, with the boss 21 located in a steer hole 23 disposed at the tail portion of the paddle-like plate 22 and the bump 20 located in a position-limiting slot 24 at the tail portion of the paddle-like plate 22; and an elastic pull rod 25 connected between two pull-blocks on the paddle-like plate 22.

In the above embodiment, when the first moveable rail 2 and the second moveable rail 8 need to be removed, the first moveable rail 2 and the second moveable rail 8 are pulled out and the paddle-like plate 22 in the anti-detachment assembly 19 is pushed, and the paddle-like plate 22 is moved downwards, thereby driving the steer hole 23 and the position-limiting slot 24 at the tail portion of the paddle-like plate 22 to move upwards by means of the elastic pull rod 25, and having the first moveable rail 22 pulled out.

A working method for immersion server slide rail is provided, which comprises slide rail opening buffering and slide rail closing buffering, specifically the steps of the working method are as follows:
Step 1: when opening the server slide rail, the first moveable rail 2 is moved outwards on the fixed rail 1 through the roller balls 13 on the sliding trestle 12, the elastic members 9 undergo a loss of pressure and push the guide pins 7 and the buffering block 11 to move outwards, and the liquid coolant of the server passes through the small holes 6 in the tail portion of the buffer tank 3 to enter the buffer chambers 5 and fills up the chambers. When the buffering block 11 abuts against the first position-limiting stopper 17, the second moveable rail 8 is also moved outwards on the first moveable rail 2 through the roller balls 13 on the first moveable rail 12, thereby completing opening of the slide rail;
Step 2: when closing the server slide rail, the second moveable rail 8 is moved inwards. The second moveable rail 8 moves outwards on the first moveable rail 2 through the roller balls 13 on the sliding trestle 12. When the second moveable rail 8 returns to its position, the first moveable rail 2 moves inwards on the fixed rail 1 through the roller balls 13 on the sliding trestle 12. When the tail portion of the first moveable rail 2 approaches the buffering block 11 and comes in contact with the buffering block 11, it continues to move inwards and the inward thrust pushes the buffering block 11, the guide pins 7 and the elastic members 9 to undergo compression, and the guide pins 7 push the server's liquid coolant in the buffer chambers 5 to flow out of the small holes 6, thereby forming a buffer.

Operating principles: during operation of the buffer structure of the present invention, when opening the slide rail, firstly the first moveable rail 2 and the second moveable rail 8 are moved outwards in sequence, then the first moveable rail 2 undergoes movement in the fixed rail 1 through the roller balls 13 on the sliding trestle 12, and the second moveable rail 8 undergoes movement in the first moveable rail 2 through the roller balls 13 on the sliding trestle 12, and the buffer structure 13 also works at the same time, the elastic members 9 undergo a loss of pressure and push the guide pins 7 and the buffering block 11 to move outwards, and the liquid coolant of the server passes through the small holes 6 in the tail portion of the buffer tank 4 to enter the buffer chambers 5 and fills up the chambers. When the buffering block 11 abuts against the first position-limiting stopper 17, the second moveable rail 8 is also moved outwards on the first moveable rail 2 through the roller balls 13 on the first moveable rail 12, thereby completing opening of the slide rail;

When closing the slide rail, the first moveable rail 2 and the second moveable rail 8 are moved inwards in sequence, then the first moveable rail 2 undergoes movement in the fixed rail 1 through the roller balls 13 on the sliding trestle 12, and the second moveable rail 8 undergoes movement in the first moveable rail 2 through the roller balls 13 on the sliding trestle 12, and when the head portion of the second moveable rail 8 comes in contact with the stopper 14 of the first moveable rail 2, the second moveable rail 8 returns to its position. At this time, the first moveable rail 2 moves inwards on the fixed rail 1 through the roller balls 13 on the sliding trestle 12, and when the tail portion of the first moveable rail 2 approaches the buffering block 11 and comes in contact with the buffering block 11, it continues to move inwards and the inward thrust pushes the buffering block 11, the guide pins 7 and the elastic members 9 to undergo compression, and the guide pins 7 push the server's liquid coolant in the buffer chambers 5 to flow out of the small holes 6, thereby forming a buffer. When the second position-limiting stopper 18 at the head portion of the first moveable rail 2 comes in contact with the stopper 14 of the fixed rail 1, the first moveable rail 2 returns to its position.

While the foregoing has provided description of preferred embodiments of the present invention with reference to the accompanying drawings, the present invention is not limited to those specific details in the embodiments and various equivalent transformations may be made to the technical solution of the present invention within the technical concept thereof, and such equivalent transformations shall fall within the scope of protection of the present invention.

What is claimed is:

1. A buffer structure for immersion server slide rail, characterized in that: it is composed of a fixed rail and a moveable rail assembly and is immersed in a liquid coolant for server;
an end of the fixed rail is provided with a buffer structure,
the buffer structure includes:
a buffer tank relatively fixedly mounted on the fixed rail,
the head portion of the buffer tank is provided with buffer chambers, and the buffer chambers have a depth not greater than the length of the buffer tank,
the tail portion of the buffer tank is provided with small holes, and the small holes communicate with the buffer chambers, respectively;
guide pins and elastic members installed in the buffer chambers, and the elastic members are arranged between the bottoms of the guide pins and the bottoms of the buffer chambers, respectively; and
a buffering block relatively fixed to the head portions of the guide pins.

2. The buffer structure for immersion server slide rail according to claim 1, characterized in that:
the moveable rail assembly comprises a first moveable rail and a second moveable rail;
the first moveable rail is located in the fixed rail, and the fixed rail and the first moveable rail are slidingly connected; the second moveable rail is located in the first moveable rail, and the second moveable rail and the first moveable rail are slidingly connected;
a sliding trestle is provided on an inner side of the fixed rail and an outer side of the first moveable rail, with the sliding trestle being provided with roller balls, the roller balls of the sliding trestle have a simultaneous surface connection with the chute on the inner side of the fixed rail and the chute on the outer side of the first moveable rail;
another sliding trestle is provided on an inner side of the first moveable rail and an outer side of the second moveable rail, with the sliding trestle being provided with roller balls, the roller balls of the sliding trestle have a simultaneous surface connection with the chute on the inner side of the first moveable rail and the chute on the outer side of the second moveable rail;
the head portion of the fixed rail and the head portion of the first moveable rail are each provided with a stopper, which is in contact with the head portion of the sliding trestle.

3. The buffer structure for immersion server slide rail according to claim 1, characterized in that:
two foolproof blocks are provided on the bottom surface of the buffer tank, two foolproof slots are opened on the fixed rail, and the foolproof blocks are located in the foolproof slots.

4. The buffer structure for immersion server slide rail according to claim 2, characterized in that:
a raised first position-limiting stopper is provided on the fixed rail, and when the buffering block is stretched out, the first position-limiting stopper limits the maximum working distance of the buffering block;
the head portion of the first moveable rail and the head portion of the second moveable rail are each provided with a second position-limiting stopper that protrudes inwards, and when the slide rail is closed, the second position-limiting stoppers limit the maximum pushed-in distance of the first moveable rail and the second moveable rail.

5. The buffer structure for immersion server slide rail according to claim 2, characterized in that:
an inner side of the tail portion of the first moveable rail and an inner side of the tail portion of the second moveable rail are each provided with an anti-detachment assembly;
the head portion of the fixed rail is provided with an inwardly protruding bump; the tail portion of the sliding trestle is provided with a boss;
the anti-detachment assembly includes: a paddle-like plate mounted on the first moveable rail by means of a rivet, with the boss located in a steer hole disposed at the tail portion of the paddle-like plate and the bump located in a position-limiting slot at the tail portion of the paddle-like plate; and an elastic pull rod connected between two pull-blocks on the paddle-like plate.

6. The buffer structure for immersion server slide rail according to claim 1, characterized in that:
the small holes are connected externally to a liquid coolant.

7. The buffer structure for immersion server slide rail according to claim 1, characterized in that:
the centers of the buffer chambers and the centers of the small holes are coaxial, respectively.

8. The buffer structure for immersion server slide rail according to claim 2, characterized in that:
the moveable rail assembly includes at least a first moveable rail and a second moveable rail, which can be increased or decreased depending on the requirements of the workplace.

9. A working method for a buffer structure for immersion server slide rail, characterized in that it comprises slide rail opening buffering and slide rail closing buffering, specifically the steps of the working method are as follows:
Step 1: when opening the server slide rail, the first moveable rail is moved outwards on the fixed rail through the roller balls on the sliding trestle, the elastic members undergo a loss of pressure and push the guide pins and the buffering block to move outwards, and the liquid coolant of the server passes through the small holes in the tail portion of the buffer tank to enter the buffer chambers and fills up the chambers. When the buffering block abuts against the first position-limiting stopper, the second moveable rail is also moved outwards on the first moveable rail through the roller balls on the first moveable rail, thereby completing opening of the slide rail;
Step 2: when closing the server slide rail, the second moveable rail is moved inwards. The second moveable rail moves outwards on the first moveable rail through the roller balls on the sliding trestle. When the second moveable rail returns to its position, the first moveable rail moves inwards on the fixed rail through the roller balls on the sliding trestle. When the tail portion of the first moveable rail approaches the buffering block and comes in contact with the buffering block, it continues to move inwards and the inward thrust pushes the buffering block, the guide pins and the elastic members to undergo compression, and the guide pins push the server's liquid coolant in the buffer chambers to flow out of the small holes, thereby forming a buffer.
